(19) United States
(12) Patent Application Publication
(10) Pub. No.: US 2009/0133908 A1
(43) Pub. Date: May 28, 2009

(54) INTERCONNECT STRUCTURE FOR A MICROELECTRONIC DEVICE, METHOD OF MANFACTURING SAME, AND MICROELECTRONIC STRUCTURE CONTAINING SAME

(76) Inventors: Michael D. Goodner, Hillsboro, OR (US); Kevin J. Lee, Beaverton, OR (US)

Correspondence Address: INTEL CORPORATION;c/o CPA Global, P.O. BOX 52050, MINNEAPOLIS, MN, 55402, US

(21) Appl. No.: 11/946,599

(22) Filed: Nov. 28, 2007

(51) Int. Cl. H05K 1/03; H01R 43/00

(52) U.S. Cl. 174/255; 29/885

(57) ABSTRACT

An interconnect structure for a microelectronic device includes an electrically conductive material (130, 730, 930) adjacent to a metallization layer (120, 320, 920). The electrically conductive material has a base (131, 931) and a body (132, 932). The base is wider than the body. The base and the body form a single monolithic structure having no internal interface. The interconnect structure may be manufactured by providing a substrate (110, 310, 910) to which the metallization layer is applied, forming a sacrificial layer (410) adjacent to the metallization layer and a resist layer (510) adjacent to the sacrificial layer, patterning the resist layer to form an opening (610) (thereby removing a portion of the sacrificial layer), placing the electrically conductive material in the opening, and removing the resist layer, the sacrificial layer, and a portion of the metallization layer.

### FIELD OF THE INVENTION

The disclosed embodiments of the invention relate generally to interconnect structures in microelectronic packaging, and relate more particularly to “top-hat” shaped interconnect structures.

### BACKGROUND OF THE INVENTION

In advanced logic devices, low-k dielectric materials are required in order to meet interconnect signal delay and power consumption requirements. Such low-k materials have proven challenging to integrate in packaged devices, as the CTE mismatch between die and package impart significant stresses during the chip join process. Left unaddressed, these stresses may lead to catastrophic cracking and failure of low-k interconnect structures. The move to lead-free bumping technology has further increased these stresses due to the low compliance of lead-free solders. To enable higher input/output (I/O) density on the die, smaller die-side bumps are required. However, small bump size decreases the area over which die-package forces are dissipated and leads to increased stresses on the underlying low-k dielectric. “Top hat” bumps, which have a wide base or brim beneath a narrower main bump mass, are one solution to provide reduced bump pitches while limiting the stress concentration effects.

### BRIEF DESCRIPTION OF THE DRAWINGS

The disclosed embodiments will be better understood from a reading of the following detailed description, taken in conjunction with the accompanying figures in the drawings in which:

FIG. 1 is a side elevational view of an interconnect structure for a microelectronic device according to an embodiment of the invention;

FIG. 2 is a flowchart illustrating a method of manufacturing an interconnect structure for a microelectronic device according to an embodiment of the invention;

FIGS. 3-8 are side elevational views of an interconnect structure at various points in a manufacturing process according to an embodiment of the invention; and

FIG. 9 is a side elevational view of a microelectronic structure according to an embodiment of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

### DETAILED DESCRIPTION OF THE DRAWINGS

In one embodiment of the invention, an interconnect structure for a microelectronic device comprises a metallization layer and an electrically conductive material adjacent to the metallization layer. The electrically conductive material has a base and a body adjacent to the base. The base is wider than the body and the base and the body form a single monolithic structure having no internal interface. In one embodiment, such an interconnect structure is manufactured by providing a substrate to which a metallization layer is applied, forming a sacrificial layer adjacent to the metallization layer and a resist layer adjacent to the sacrificial layer, patterning the resist layer such that an opening is formed in the resist layer and such that a portion of the sacrificial layer is removed, placing an electrically conductive material in the opening, and removing the resist layer, the sacrificial layer, and a portion of the metallization layer.

Top-hat shaped copper bumps have been shown to provide improved low-k dielectric cracking performance. The top-hat shape has a wide base, which distributes die-package interaction induced stresses over a much larger area (thus reducing the stress and damage to the underlying backend low-k dielectric layer), and also has a narrower main bump diameter which enables acceptable underfill flow with bump pitches below 175 micrometers (μm).

Unfortunately, the current top-hat bump formation process requires two separate sequences of “lithography-plating-resist strip” steps, making the process very expensive. More specifically, top hat bumps are currently formed in a two-step process that includes patterning a resist to define the “brim” (wider base), plating the brim, stripping the resist, and then repeating the patterning-plating-stripping process sequence to form the main mass or body of the bump.

Embodiments of the invention enable top-hat bumps to be formed using a single mask lithography process, or in other words a single “lithography-plating-resist strip” sequence. The single mask process is significantly less expensive than existing two-mask processes, and also offers self-alignment and reliability advantages.

In particular, forming a top-hat bump with a single mask process significantly reduces the process cost by eliminating one lithography step, one plating step, and one resist strip step while introducing only an additional spin-coating step and possibly one etch or strip step. Furthermore, plating the top-hat bump in a single step eliminates an internal interface created during the two-mask process, thus improving the reliability of the bump. The single-step process also eliminates any mis-registration or alignment difficulties that would otherwise be encountered when trying to pattern the mass of the bump on top of the brim, which is to say that the bump “brim” and bump “main body” are self-aligned.

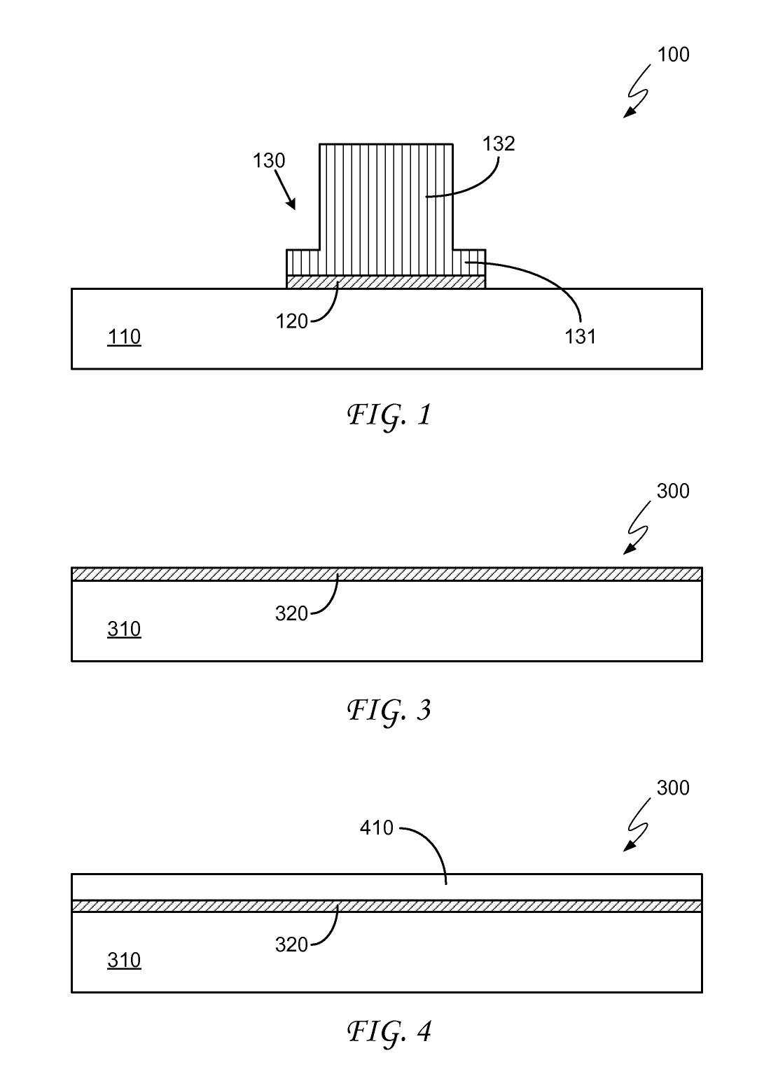

Referring now to the drawings, FIG. 1 is a side elevational view of an interconnect structure 100 for a microelectronic device according to an embodiment of the invention. As illustrated in FIG. 1, interconnect structure 100 comprises a substrate 110, a metallization layer 120 adjacent to substrate 110, and an electrically conductive material 130 adjacent to metallization layer 120. Electrically conductive material 130 comprises a base 131 and a body 132 adjacent to base 131. Base 131 is wider than body 132. Because of the way they are manufactured (discussed below) base 131 and body 132 form a single monolithic structure having no internal interface. Such a structure may be more reliable than one with an internal interface because, among other possible reasons, the internal interface may have contamination or irregularities that reduce the reliability of the interconnect structure.

In one embodiment, substrate 110 comprises a low-k dielectric material such as silicon dioxide doped with fluorine or carbon, porous silicon dioxide, or the like. In an embodiment, a “low-k” dielectric material is a material having a dielectric constant that is no greater than 3.5 (the dielectric constant of unaltered silicon dioxide is approximately 4.0-4.2) and in some cases as low as 2.0 or even lower. As an example, substrate 110 can be an integrated circuit die that contains low-k dielectric material such as that described above.

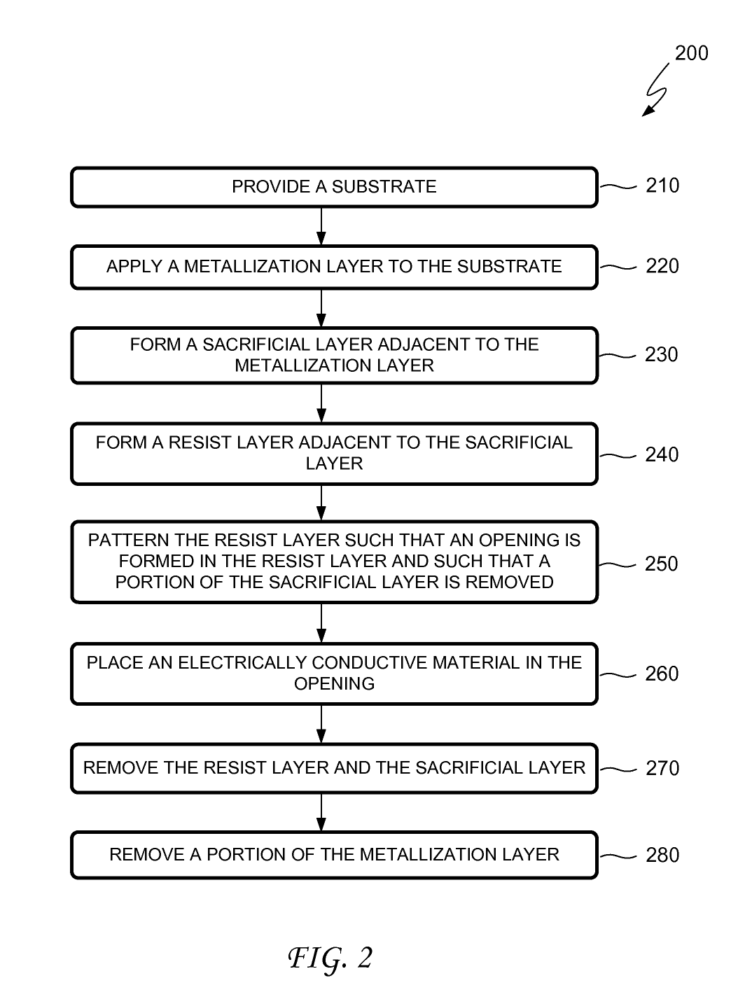

FIG. 2 is a flowchart illustrating a method 200 of manufacturing an interconnect structure for a microelectronic device according to an embodiment of the invention. A step 210 of method 200 is to provide a substrate. As an example, the substrate can be similar to substrate 110 that is shown in FIG. 1. As another example, the substrate can be similar to a substrate 310 that is first shown in FIG. 3, which is a side elevational view of an interconnect structure 300 at a particular point in a manufacturing process according to an embodiment of the invention. It should be understood that substrate 310 can be similar to substrate 110 and, accordingly, that substrate 310 can be an integrated circuit die that contains low-k dielectric material.

A step 220 of method 200 is to apply a metallization layer to the substrate. As an example, the metallization layer can be similar to metallization layer 120 that is shown in FIG. 1. As another example, the metallization layer can be similar to a metallization layer 320 that is first shown in FIG. 3.

A step 230 of method 200 is to form a sacrificial layer adjacent to the metallization layer. A purpose of the sacrificial layer is to enable the easy formation under the resist layer of an undercut that allows the base or rim of the top-hat bump to be formed. As an example, the sacrificial layer can be similar to a sacrificial layer 410 that is first shown in FIG. 4, which is a side elevational view of interconnect structure 300 at a particular point in a manufacturing process according to an embodiment of the invention. In one embodiment, step 230 comprises depositing the sacrificial layer using a spin-coating technique. In other embodiments, step 230 comprises depositing the sacrificial layer using a vapor deposition technique, a thermal deposition technique, or the like.

Potential materials for the sacrificial layer are materials that can be isotropically etched in photoresist developer without damaging the base layer metallization (BLM) (i.e., the metallization layer) or the resist layer, and are compatible with bump plating chemistries. In one embodiment, the sacrificial layer is a lift-off layer material such as, for example, LOL-2000 (and others) that are available from Shipley Company of Marlborough, Mass. As an example, the lift-off layer material may be marginally soluble in developer, which allows the amount of an undercut (to be discussed below) to be controlled by develop time.

In a different embodiment, the sacrificial layer is an inorganic film such as CVD (chemical vapor deposition) silicon dioxide, thermal silicon dioxide, or the like. In another embodiment, the sacrificial layer is a siloxane material such as uncured methyl silsesquioxane (MSQ), hydrogen silsesquioxane (HSQ), sacrificial light-absorbing material (SLAM), or the like. In other embodiments, the sacrificial layer is a spin-on polymer such as uncured polyimides and polyimide precursors, or an anti-reflective coating such as a developable bottom anti-reflective coating (DBARC) available from, for example, AZ Electronic Materials with a U.S. office in Branchburg, N.J., or a lift-off application that uses an anti-reflective coating as the lift-off layer, such as applications available from Brewer Science, Rolla, Mo.

It should be noted at this point that SLAM, MSQ, and HSQ are typically engineered to be resistant to photoresist developer, and that silicon dioxide is definitely resistant to it as well. Accordingly, embodiments that use silicon dioxide, MSQ, HSQ, or SLAM or the like as the sacrificial layer would likely require an additional etch step, rather than the photoresist developer, to form the undercut. The separation of resist layer patterning and undercut formation into different steps or sub-steps is further discussed below.

With respect to uncured polyimides and polyimide precursors, processing may proceed as with traditional polyimide buffer coat processes, in which a non-photosensitive polyimide precursor (or uncured polyimide) is spin-coated onto the wafer and then a photoresist is applied and patterned on top of the polyimide precursor/uncured polyimide. During the photoresist develop process, the photoresist developer also isotropically etches the polyimide precursor/uncured polyimide beneath the resist openings, and the amount of undercut in the polyimide precursor/uncured polyimide beneath the photoresist is altered by modulating the develop time.

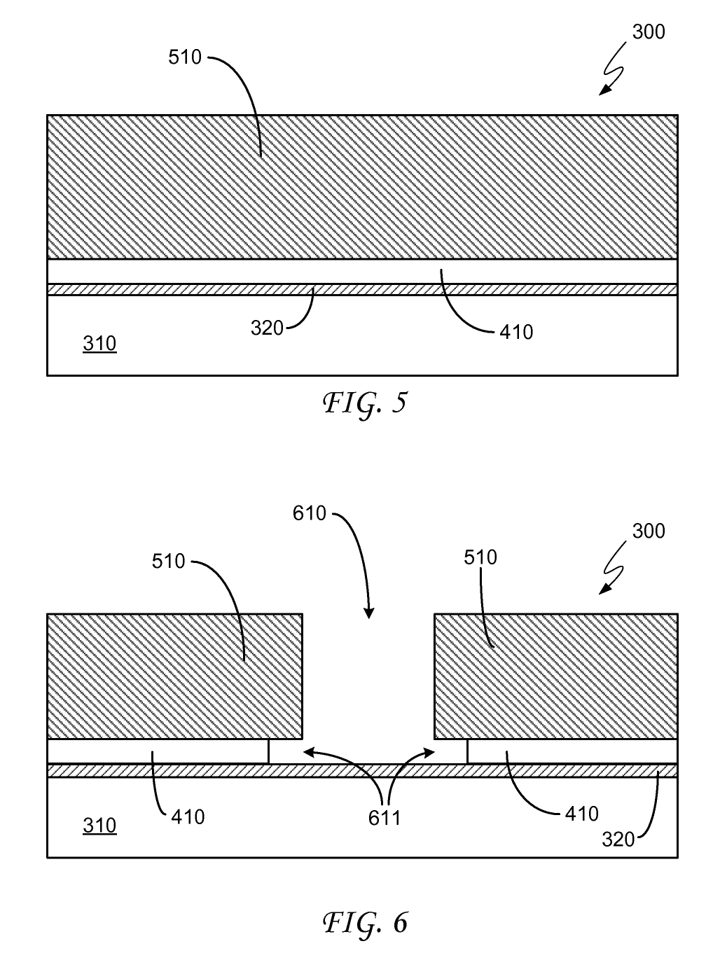

A step 240 of method 200 is to form a resist layer adjacent to the sacrificial layer. As an example, the resist layer can be similar to a resist layer 510 that is first shown in FIG. 5, which is a side elevational view of interconnect structure 300 at a particular point in a manufacturing process according to an embodiment of the invention. In one embodiment, step 240 comprises depositing the resist layer using a spin-coating technique. In other embodiments, step 240 comprises depositing the resist layer using a lamination technique, a screen printing technique, or the like.

As mentioned above, an advantage of having the sacrificial material present is that it is somewhat soluble in developer, allowing an undercut to be generated during resist develop and allowing the amount of the undercut to be controlled via develop time. It should be noted here that the undercut is perfectly aligned to the opening, eliminating the alignment issues that arise when trying to open the bump area over the base in two-mask processes.

A step 250 of method 200 is to pattern the resist layer such that an opening is formed in the resist layer and such that a portion of the sacrificial layer is removed. As an example, the opening can be similar to an opening 610 that is first shown in FIG. 6, which is a side elevational view of an interconnect structure 300 at a particular point in a manufacturing process according to an embodiment of the invention. As another example, the opening can be created using a hydrofluoric acid (HF)-based solution.

In one embodiment, step 250 comprises forming an undercut in the sacrificial layer that is aligned to the opening. As an example, such an undercut can be similar to undercuts 611 that extend underneath ledges formed by resist layer 510 as illustrated in FIG. 6. In one embodiment, step 250 or another step comprises controlling a dimension of the undercut by adjusting a length of time during which the resist layer is patterned.

In one embodiment, step 250 comprises patterning the bump location (i.e., creating the opening) in the bump layer resist (i.e., the resist layer) and simultaneously etching back the sacrificial material to form a controlled amount of undercut beneath the bottom edges of the bump layer photoresist. In another embodiment, the bump location is patterned and the undercut formed separately. In one manifestation of that latter embodiment, step 250 comprises two or more sub-steps. In a first sub-step, the resist layer is patterned (exposed and developed) in order to form the opening in the resist layer. In a second sub-step, the sacrificial layer is removed from the resist opening and an undercut occurs beneath the resist layer. This embodiment may be used, for example, where the sacrificial layer is a thermal oxide that would not be chemically altered by the resist developer. For some (though not all) photoresist materials the creation of the undercut may be more easily controlled when the resist layer and the sacrificial layer are patterned in separate sub-steps such as in the sequence described above. It should be understood that an embodiment as described using sub-steps as part of step 250 still contains fewer steps than existing two-mask top-hat bump creation processes.

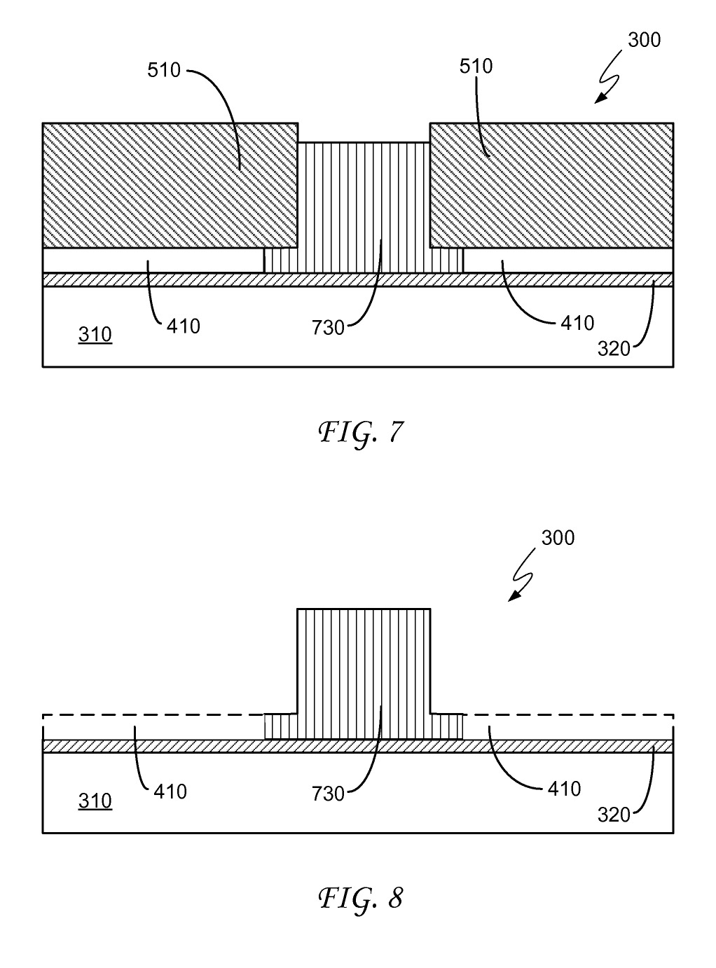

A step 260 of method 200 is to place an electrically conductive material in the opening. As an example, the electrically conductive material can be similar to electrically conductive material 130 that is shown in FIG. 1. As another example, the electrically conductive material can be similar to an electrically conductive material 730 that is first shown in FIG. 7, which is a side elevational view of interconnect structure 300 at a particular point in a manufacturing process according to an embodiment of the invention. In one embodiment, step 260 comprises using a single plating process to simultaneously plate the undercut and the opening with the electrically conductive material. In the same or another embodiment, step 260 comprises plating top-hat bumps during a single plating step using the patterned bump resist/sacrificial layer as a mold.

As has been mentioned elsewhere herein, the plating of the top-hat bump in a single step generates a monolithic bump with no internal interfaces. This is an improvement over existing two-mask processes where the top of the top-hat base is exposed to multiple chemicals and process steps, thus creating a surface which may have contamination or irregularities and reducing the reliability of the interface with the body of the bump.

A step 270 of method 200 is to remove the resist layer and, in some embodiments, the sacrificial layer. FIG. 8 is a side elevational view depicting interconnect structure 300 following the performance of step 270 according to embodiments of the invention. As illustrated in FIG. 8, resist layer 510 has been etched away, stripped, or otherwise removed, leaving electrically conductive material 730 sitting atop metallization layer 320 and substrate 310. Sacrificial layer 410 is shown in dotted lines in FIG. 8, signifying that in some embodiments it is removed while in other it is permitted to remain, as will be further discussed below.

It should be understood that step 270 removes the portions of resist layer 510 and (where applicable) of sacrificial layer 410 that remain after the creation of opening 610 and undercuts 611 (see FIG. 6). In other words, the creation of opening 610 and undercuts 611 (which in at least one embodiment are part of opening 610) removes some of resist layer 510 and some of sacrificial layer 410; the portions of those layers that remain after the formation of opening 610 and undercuts 611 are removed in step 270.

In an embodiment, step 270 comprises two or more sub-steps. This embodiment may be used, for example, in cases where the resist layer and the sacrificial layer are patterned in separate steps or sub-steps, as discussed above in connection with step 250, such as where the sacrificial layer is a thermal oxide that would not be chemically altered by the resist developer. In a first sub-step of step 270, the resist layer (i.e., that portion of the resist layer remaining following the formation of the opening therein) is removed. As an example, this may be accomplished using a normal resist stripper. In a second sub-step of step 270, the sacrificial layer (i.e., that portion of the sacrificial layer remaining after undercuts are formed therein) is removed. As an example, this may be accomplished using an etch chemistry unique to or tailored to the material making up the sacrificial layer. As a particular example, where the sacrificial layer is an oxide it may be removed using a dry etch or an HF solution. It should be understood that an embodiment as described using sub-steps as part of step 270 still contains fewer steps than existing two-mask top-hat bump creation processes.

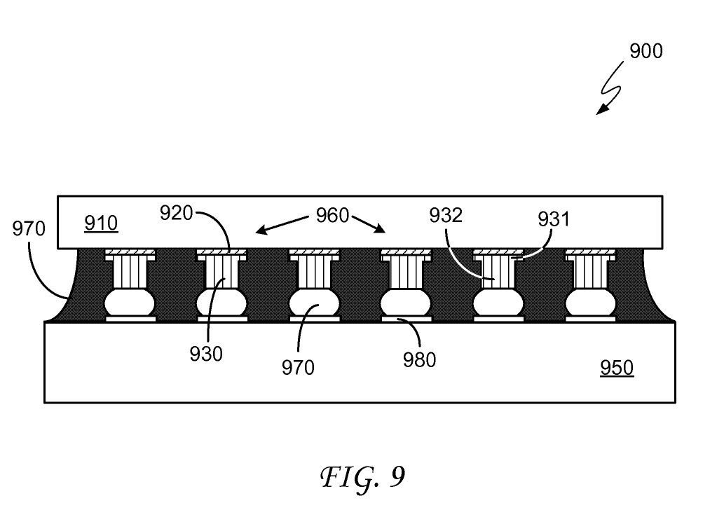

In another embodiment, as discussed above, step 270 comprises removing the resist layer but not the sacrificial layer. In that embodiment the sacrificial layer is permitted to remain as a permanent film on the substrate. As an example, the sacrificial layer may be permitted to remain in cases where the sacrificial layer comprises silicon dioxide or polyimide. It should be noted that in an embodiment where the sacrificial layer is not removed in step 270 portions of a microelectronic structure that contains the sacrificial layer may be electrically shorted together, as further explained below in connection with FIG. 9.

A step 280 of method 200 is to remove a portion of the metallization layer, thereby exposing the bump BLM. The performance of step 280 results in the creation of an electrically-isolated top-hat shaped bump on substrate 310.

In one embodiment, step 280 comprises etching away or otherwise removing the metallization layer everywhere except underneath the electrically conductive material, resulting in a structure like interconnect structure 100 that is shown in FIG. 1. In an embodiment where the sacrificial layer remains as a permanent film, step 280 comprises removing the metallization layer in those places, if any, where it is exposed and leaving the metallization layer in those places where it is covered by the sacrificial layer.

It may easily be seen that interconnect structure 300 as depicted in FIG. 8 (ignoring the dotted line regions) may be converted to a structure substantially similar to interconnect structure 100 of FIG. 1 simply by removing that portion of metallization layer 320 that is not covered by electrically conductive material 730.

FIG. 9 is a side elevational view of a microelectronic structure 900 according to an embodiment of the invention. As illustrated in FIG. 9, microelectronic structure 900 comprises a substrate 910 and a package substrate 950 attached to substrate 910 with a plurality of interconnect structures 960, a plurality of solder bumps 970, and a plurality of pads 980. Each one of plurality of interconnect structures 960 comprises a metallization layer 920 and an electrically conductive material 930 adjacent to metallization layer 920. As an example, substrate 910, interconnect structures 960, metallization layer 920, and electrically conductive material 930 can be similar to, respectively, substrate 110, interconnect structure 100, metallization layer 120, and electrically conductive material 130, all of which are shown in FIG. 1.

FIG. 9 further illustrates that metallization layer 920 lies adjacent to substrate 910, electrically conductive material 930 has a base 931 and a body 932 adjacent to base 931, base 931 is wider than body 932, and base 931 and body 932 form a single monolithic structure having no internal interface. An underfill material 970 is located between package substrate 950 and substrate 910 and at least partially surrounds plurality of interconnect structures 960. In one embodiment, adjacent ones of plurality of interconnect structures 960 are separated by a separation distance of no more than 175 micrometers.

As mentioned above, if the sacrificial layer is permitted to remain as a permanent film on substrate 910, solder bumps 970 will be electrically shorted together through the unetched metallization layer 920 beneath the sacrificial layer. It will be understood that if all of the solder bumps on the entire die were electrically shorted together the chip would not function electrically. As an example, however, it may be desirable to electrically connect together certain subsets of the solder bumps in a situation where all of the solder bumps that are electrically shorted together are of the same type, such as where a plurality of power bumps are electrically shorted together or where a plurality of ground bumps are electrically shorted together.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the interconnect structures and related methods discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

1. An interconnect structure for a microelectronic device, the interconnect structure comprising:
a metallization layer; and
an electrically conductive material adjacent to the metallization layer,
wherein:
the electrically conductive material has a base and a body adjacent to the base;
the base is wider than the body; and
the base and the body form a single monolithic structure having no internal interface.

2. The interconnect structure of claim 1 wherein:
the base takes its shape from a sacrificial lift-off layer material.

3. The interconnect structure of claim 1 wherein:
the base takes its shape from a sacrificial inorganic film.

4. The interconnect structure of claim 1 wherein:
the base takes its shape from a sacrificial siloxane material.

5. The interconnect structure of claim 1 wherein:
the base takes its shape from a sacrificial anti-reflective coating.

6. The interconnect structure of claim 1 wherein:
the base takes its shape from a sacrificial spin-on polymer.

7. A method of manufacturing an interconnect structure for a microelectronic device, the method comprising:
providing a substrate;
applying a metallization layer to the substrate;
forming a sacrificial layer adjacent to the metallization layer, the sacrificial layer formed from a material other than a resist material;
forming a resist layer adjacent to the sacrificial layer;
patterning the resist layer such that an opening is formed in the resist layer and a portion of the sacrificial layer is removed, where the removed portion of the sacrificial layer is wider than the opening formed in the resist layer;
placing an electrically conductive material in the opening;
removing the resist layer; and
removing a portion of the metallization layer.

8. The method of claim 7 further comprising:
removing the sacrificial layer.

9. The method of claim 7 wherein:
forming the sacrificial layer comprises depositing the sacrificial layer using a spin-coating technique.

10. The method of claim 7 wherein:
forming the resist layer comprises depositing the resist layer using a spin-coating technique.

11. The method of claim 7 wherein:
patterning the resist layer comprises forming an undercut in the sacrificial layer that is aligned to the opening such that a first portion of the undercut located at a first side of the opening is substantially equal in size to a second portion of the undercut located at a second side of the opening opposite the first side.

12. The method of claim 11 further comprising:
controlling a dimension of the undercut by adjusting a length of time during which the resist layer is patterned.

13. The method of claim 11 wherein:
placing the electrically conductive material comprises using a single plating process to simultaneously plate the undercut and the opening with the electrically conductive material.

14. A method of manufacturing an interconnect structure for a microelectronic device, the method comprising:
providing a substrate with a metallization layer thereon;
forming a sacrificial layer adjacent to the metallization layer, the sacrificial layer formed from a material other than a resist material;
forming a resist layer adjacent to the sacrificial layer;
patterning the resist layer such that an opening is formed in the resist layer;
removing a portion of the sacrificial layer under the opening in the resist layer in order to form an undercut region;
placing an electrically conductive material in the opening and in the undercut region;
removing the resist layer; and
removing a portion of the metallization layer.

15. The method of claim 14 further comprising:
removing the sacrificial layer.

16. The method of claim 14 further comprising:
controlling a dimension of the undercut region by adjusting a length of time during which the resist layer is patterned.

17. The method of claim 14 wherein:
forming the sacrificial layer comprises depositing the sacrificial layer using one of a spin-coating technique, a vapor deposition technique, and a thermal deposition technique.

18. The method of claim 14 wherein:
forming the resist layer comprises depositing the resist layer using one of a spin-coating technique, a lamination technique, and a screen printing technique.

19. The method of claim 14 wherein:
placing the electrically conductive material comprises using a single plating process to simultaneously plate the undercut region and the opening with the electrically conductive material.

20. A microelectronic structure comprising:
a substrate; and
a package attached to the substrate with a plurality of interconnect structures, each one of the plurality of interconnect structures comprising:
a metallization layer; and
an electrically conductive material adjacent to the metallization layer,
wherein:
the metallization layer lies adjacent to the substrate;
the electrically conductive material has a base and a body adjacent to the base;
the base is wider than the body; and
the base and the body form a single monolithic structure having no internal interface.

21. The microelectronic structure of claim 20 further comprising:
an underfill material between the package and the substrate and at least partially surrounding the plurality of interconnect structures.

22. The microelectronic structure of claim 20 wherein:
the substrate comprises a dielectric material having a dielectric constant that is no greater than 3.5.

23. The microelectronic structure of claim 20 wherein:
the base is shaped like an undercut in one of a sacrificial lift-off layer material, a sacrificial inorganic film, and a sacrificial siloxane material.

24. The microelectronic structure of claim 20 wherein:
the base is shaped like an undercut in one of a sacrificial anti-reflective coating and a sacrificial spin-on polymer.

25. The microelectronic structure of claim 20 wherein:
adjacent ones of the plurality of interconnect structures are separated by a separation distance; and
the separation distance is no greater than 175 micrometers.
